(19) United States
(12) Patent Application Publication
(10) Pub. No.: US 2004/0058253 A1
(43) Pub. Date: Mar. 25, 2004

(54) Mirror for exposure system, reflection mask for exposure system, exposure system and pattern formation method

(75) Inventors: Masayuki Endo, Osaka (JP); Masaru Sasago, Osaka (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD

(21) Appl. No.: 10/641,114

(22) Filed: Aug. 15, 2003

(30) Foreign Application Priority Data
Sep. 25, 2002 (JP) 2002-278489

(51) Int. Cl. G03F 1/00; G02B 5/08; G02B 5/20; F21V 9/04; F21V 9/06; G02B 5/26; G03F 7/20; G03F 7/40; C23C 14/12; C23C 14/34; G02B 17/00; G02B 21/00; G02B 23/00; G03B 27/58; G03B 27/62; G03B 27/70

(52) U.S. Cl. 430/5; 359/359; 359/361; 359/884; 430/311; 430/313; 204/192.27; 204/192.28; 359/365; 355/47; 355/66

(57) ABSTRACT

A mirror for use in an exposure system of this invention includes a reflection layer for reflecting EUV formed on a mirror substrate and an absorption layer formed on the reflection layer and made from a compound for absorbing infrared light.

### BACKGROUND OF THE INVENTION

The present invention relates to an exposure system, a mirror and a reflection mask of the exposure system and a pattern formation method for use in fabrication process for semiconductor devices.

In accordance with the increased degree of integration of semiconductor integrated circuits and downsizing of semiconductor devices, there are increasing demands for further rapid development of lithography technique.

In the current lithography technique, pattern formation is carried out by using exposing light of a mercury lamp, KrF excimer laser, ArF excimer laser or the like. Also, in order to form a fine pattern with a pattern width of 0.1 μm or less, and more particularly, of 70 nm or less, use of exposing light of a further shorter wavelength, such as vacuum UV like F₂ laser (of a wavelength of a 157 nm band) or extreme UV (EUV) (of a wavelength of a 1 nm through 30 nm band), as well as use of EB employing electron beam (EB) projection exposure or the like is being studied.

Among these exposing light, EUV is regarded particularly promising because it can be used for forming a pattern with a pattern width of 50 nm or less.

Now, the whole architecture of an EUV exposure system described in, for example, “Recent advances of three-aspherical-mirror system for EUVL” (H. Kinoshita et al., Proc. SPIE, vol. 3997, 70 (2000) (issued in July 2000)) will be described with reference to FIG. 4.

As shown in FIG. 4, EUV emitted from an EUV source 10 of laser plasma, SOR or the like is selectively reflected by a reflection mask 20, and then is successively reflected by a first reflection mirror 30a, a second reflection mirror 30b, a third reflection mirror 30c and a fourth reflection mirror 30d, so as to irradiate a resist film formed on a semiconductor wafer 40.

Now, a conventional pattern formation method performed by using this EUV exposure system will be described with reference to FIGS. 5A through 5D.

First, a chemically amplified resist material having the following composition is prepared:

Base polymer: poly((p-t-butyloxycarbonyloxystyrene)−(hydroxystyrene)) (wherein p-t-butyloxycarbonyloxystyrene: hydroxystyrene=40 mol %:60 mol %) . . . 4.0 g

Acid generator: triphenylsulfonium nonafluorobutanesulfonate . . . 0.12 g

Solvent: propylene glycol monomethyl ether acetate . . . 20 g

Next, as shown in FIG. 5A, the aforementioned chemically amplified resist material is applied on a substrate 1, so as to form a resist film 2 with a thickness of 0.15 μm.

Then, as shown in FIG. 5B, pattern exposure is carried out by irradiating the resist film 2 with EUV 3 (of a wavelength of a 13.5 nm band) having been emitted by the EUV exposure system with numerical aperture (NA) of 0.10 and reflected by the reflection mask.

After the pattern exposure, as shown in FIG. 5C, the resist film 2 is subjected to post-exposure bake with a hot plate at a temperature of 100° C. for 60 seconds. Thus, an exposed portion 2a of the resist film 2 becomes soluble in an alkaline developer because an acid is generated from the acid generator therein while an unexposed portion 2b of the resist film 2 remains to be insoluble in an alkaline developer because no acid is generated from the acid generator therein.

After the post-exposure bake, the resist film 2 is developed with a 2.38 wt % tetramethylammonium hydroxide developer (alkaline developer). Thus, a resist pattern 4 made of the unexposed portion 2b of the resist film 2 can be obtained as shown in FIG. 5D.

The resist pattern 4 is, however, in a degraded pattern shape as shown in FIG. 5D, and has a pattern width of approximately 72 nm, which is smaller by approximately 20% than the mask pattern width (90 nm).

When the resist pattern 4 in such a defective shape is used as a mask for etching a target film, the resultant pattern is also in a defective shape, which is a serious problem in the fabrication process for semiconductor devices.

### SUMMARY OF THE INVENTION

In consideration of the aforementioned conventional problem, an object of the invention is preventing degradation of a resist pattern formed by developing a resist film having been selectively irradiated with EUV.

In order to achieve the object, the present inventors have made various examinations on the cause of the degradation of the resist pattern, resulting in finding the following: The exposing light used for irradiating the resist film includes light other than EUV, that is, specifically infrared light, and the infrared light is thermally absorbed locally by the exposed portion of the resist film. A portion of the resist film that has thermally absorbed the infrared light is deformed, and therefore, the size controllability for the resist pattern is lowered. Now, the mechanism of the lowering in the size controllability for the resist film derived from the local thermal absorption of the infrared light will be described in detail.

Since high heat caused by the infrared light having entered the exposed portion 2a of the resist film 2 is propagated to the unexposed portion 2b of the resist film 2 in a moment, the temperature of the base polymer is increased to be higher than the softening point in the unexposed portion 2b. Therefore, the resist pattern 4 made of the unexposed portion 2b obtained after the development is deformed, and this seems to lower the pattern size controllability. In the exposed portion 2a of the resist film 2, the reaction of the base polymer caused by the EUV 3 occurs in the ordinary manner. Therefore, the exposed portion 2a is minimally affected by the heat caused by the infrared light and hence can be removed through the development in the ordinary manner.

The phenomenon in which the infrared light included in the EUV emitted from the EUV source 1 is absorbed by the unexposed portion 2b of the resist film 2 is also described in “EXTATIC, ASML's alpha-tool development for EUVL” (H. Meiling et al., Proc. SPIE, vol. 4688, 52(2002) (issued in July 2002)).

In this manner, the present inventors have found that the deformation of a resist pattern made of an unexposed portion of a resist film obtained after development is derived from high heat locally absorbed by an exposed portion of the resist film.

The present invention was devised on the basis of this finding and is specifically practiced as follows:

The mirror for use in an exposure system of this invention includes a reflection layer for reflecting EUV formed on a mirror substrate; and an absorption layer formed on the reflection layer and made from a compound for absorbing infrared light.

In the mirror for use in an exposure system of this invention, the absorption layer made from the compound for absorbing infrared light is formed on the reflection layer, and therefore, infrared light included in exposing light of EUV is absorbed by the absorption layer when reflected by the mirror. Accordingly, the quantity of infrared light included in the exposing light used for irradiating a resist film is reduced. As a result, the local thermal absorption by the resist film can be reduced, so that the shape of a resist pattern obtained by developing the resist film can be prevented from degrading.

In the mirror for use in an exposure system of this invention, the compound is preferably phthalocyanine.

Since phthalocyanine well absorbs infrared light, infrared light is minimally included in the exposing light used for irradiating the resist film. Therefore, the local thermal absorption by the resist film can be definitely avoided, and the shape of the resist pattern can be definitely prevented from degrading. Furthermore, since phthalocyanine minimally absorbs EUV, the quantity of EUV used for irradiating the resist film is not reduced, and the sensitivity and the resolution of the resist pattern are minimally lowered. Moreover, phthalocyanine is very stable in a high vacuum atmosphere in which the resist film is irradiated with EUV.

In this case, the phthalocyanine can be copper phthalocyanine, titanium monoxide phthalocyanine, titanium phthalocyanine, hydrogen phthalocyanine, aluminum phthalocyanine, iron phthalocyanine, cobalt phthalocyanine, tin phthalocyanine, copper fluoride phthalocyanine, copper chloride phthalocyanine, copper bromide phthalocyanine or copper iodide phthalocyanine.

In the mirror for use in an exposure system of this invention, the compound is preferably a cyanine compound, a squalilium compound, an azomethine compound, a xanthene compound, an oxonol compound, an azo compound, an anthraquinone compound, a triphenylmethane compound, a phenothiazine compound or a phenoxazine compound.

In the mirror for use in an exposure system of this invention, the compound is preferably deposited by sputtering, vacuum evaporation or ion plating.

In this case, the sputtering can be magnetron sputtering, reactive sputtering, diode sputtering, ion beam sputtering, facing target sputtering, ECR sputtering, multiode sputtering or coaxial sputtering; the vacuum evaporation can be molecular beam epitaxial growth, reactive vacuum evaporation, electron beam evaporation, laser beam evaporation, arc process, resistance heating evaporation or induction heating evaporation; and the ion plating can be reactive ion plating, ion beam process or hollow cathode discharge ion plating.

The reflection mask for use in an exposure system of this invention includes a reflection layer for reflecting EUV formed on a mask substrate; an EUV absorption layer for absorbing EUV selectively formed on the reflection layer; and an infrared light absorption layer formed above the reflection layer at least in a portion where the EUV absorption layer is not formed and made from a compound for absorbing infrared light.

In the reflection mask for use in an exposure system of this invention, the infrared light absorption layer made from the compound for absorbing infrared light is formed above the reflection layer at least in the portion where the EUV absorption layer is not formed. Therefore, infrared light included in exposing light of EUV is absorbed by the infrared light absorption layer when reflected by the reflection mask, and hence, the quantity of infrared light included in the exposing light used for irradiating a resist film is reduced. As a result, the local thermal absorption by the resist film can be reduced, and the shape of a resist pattern obtained by developing the resist film can be prevented from degrading.

In the reflection mask for use in an exposure system of this invention, the compound is preferably phthalocyanine.

Since phthalocyanine well absorbs infrared light and minimally absorbs EUV as described above, the shape of the resist pattern can be definitely prevented from degrading, and the sensitivity and the resolution of the resist pattern are minimally lowered.

In this case, the phthalocyanine can be copper phthalocyanine, titanium monoxide phthalocyanine, titanium phthalocyanine, hydrogen phthalocyanine, aluminum phthalocyanine, iron phthalocyanine, cobalt phthalocyanine, tin phthalocyanine, copper fluoride phthalocyanine, copper chloride phthalocyanine, copper bromide phthalocyanine or copper iodide phthalocyanine.

In the reflection mask for use in an exposure system of this invention, the compound is preferably a cyanine compound, a squalilium compound, an azomethine compound, a xanthene compound, an oxonol compound, an azo compound, an anthraquinone compound, a triphenylmethane compound, a phenothiazine compound or a phenoxazine compound.

In the reflection mask for use in an exposure system of this invention, the compound is preferably deposited by sputtering, vacuum evaporation or ion plating.

In this case, the sputtering can be magnetron sputtering, reactive sputtering, diode sputtering, ion beam sputtering, facing target sputtering, ECR sputtering, multiode sputtering or coaxial sputtering; the vacuum evaporation can be molecular beam epitaxial growth, reactive vacuum evaporation, electron beam evaporation, laser beam evaporation, arc process, resistance heating evaporation or induction heating evaporation; and the ion plating can be reactive ion plating, ion beam process or hollow cathode discharge ion plating.

The first exposure system of this invention includes a mirror, which includes a reflection layer for reflecting EUV formed on a mirror substrate; and an absorption layer formed on the reflection layer and made from a compound for absorbing infrared light.

In the first exposure system of this invention, since the absorption layer made from the compound for absorbing infrared light is formed on the reflection layer of the mirror, infrared light included in exposing light of EUV is absorbed by the absorption layer when reflected by the mirror. Therefore, the quantity of infrared light included in the exposing light used for irradiating a resist film is reduced. As a result, the local thermal absorption by the resist film can be reduced, and the shape of a resist pattern obtained by developing the resist film can be prevented from degrading.

The second exposure system of this invention includes a reflection mask, which includes a reflection layer for reflecting EUV formed on a mask substrate; an EUV absorption layer for absorbing EUV selectively formed on the reflection layer; and an infrared light absorption layer formed above the reflection layer at least in a portion where the EUV absorption layer is not formed and made from a compound for absorbing infrared light.

In the second exposure system of this invention, since the infrared light absorption layer made from the compound for absorbing infrared light is formed above the reflection layer of the reflection mask at least in the portion where the EUV absorption layer is not formed, infrared light included in exposing light of EUV is absorbed by the infrared absorption layer when reflected by the reflection mask. Therefore, the quantity of infrared light included in the exposing light used for irradiating a resist film is reduced. As a result, the local thermal absorption by the resist film can be reduced, and the shape of a resist pattern obtained by developing the resist film can be prevented from degrading.

The third exposure system of this invention includes a mirror including a reflection layer for reflecting EUV formed on a mirror substrate and an absorption layer formed on the reflection layer and made from a compound for absorbing infrared light; and a reflection mask including a reflection layer for reflecting EUV formed on a mask substrate, an EUV absorption layer for absorbing EUV selectively formed on the reflection layer, and an infrared light absorption layer formed above the reflection layer at least in a portion where the EUV absorption layer is not formed and made from a compound for absorbing infrared light.

In the third exposure system of this invention, the absorption layer made from the compound for absorbing infrared light is formed on the reflection layer of the mirror, and the infrared light absorption layer made from the compound for absorbing infrared light is formed above the reflection layer of the reflection mask at least in the portion in which the EUV absorption layer is not formed. Therefore, the quantity of infrared light included in the exposing light used for irradiating a resist film is largely reduced. As a result, the shape of a resist pattern obtained by developing the resist film can be definitely prevented from degrading.

In each of the first through third exposure systems of this invention, the compound is preferably phthalocyanine.

Since phthalocyanine well absorbs infrared light and minimally absorbs EUV as described above, the shape of the resist pattern can be definitely prevented from degrading and the sensitivity and the resolution of the resist pattern are minimally lowered.

In this case, the phthalocyanine can be copper phthalocyanine, titanium monoxide phthalocyanine, titanium phthalocyanine, hydrogen phthalocyanine, aluminum phthalocyanine, iron phthalocyanine, cobalt phthalocyanine, tin phthalocyanine, copper fluoride phthalocyanine, copper chloride phthalocyanine, copper bromide phthalocyanine or copper iodide phthalocyanine.

In each of the first through third exposure systems of this invention, the compound is preferably a cyanine compound, a squalilium compound, an azomethine compound, a xanthene compound, an oxonol compound, an azo compound, an anthraquinone compound, a triphenylmethane compound, a phenothiazine compound or a phenoxazine compound.

In each of the first through third exposure systems of this invention, the compound is preferably deposited by sputtering, vacuum evaporation or ion plating.

In this case, the sputtering can be magnetron sputtering, reactive sputtering, diode sputtering, ion beam sputtering, facing target sputtering, ECR sputtering, multiode sputtering or coaxial sputtering; the vacuum evaporation can be molecular beam epitaxial growth, reactive vacuum evaporation, electron beam evaporation, laser beam evaporation, arc process, resistance heating evaporation or induction heating evaporation; and the ion plating can be reactive ion plating, ion beam process or hollow cathode discharge ion plating.

The first pattern formation method of this invention includes the steps of performing pattern exposure by irradiating a resist film formed on a substrate with EUV having been reflected by a reflection mask and a mirror; and forming a resist pattern made of an unexposed portion of the resist film by developing the resist film after the pattern exposure, and the mirror includes a reflection layer for reflecting EUV formed on a mirror substrate and an absorption layer formed on the reflection layer and made from a compound for absorbing infrared light.

In the first pattern formation method of this invention, since the absorption layer made from the compound for absorbing infrared light is formed on the reflection layer of the mirror, infrared light included in exposing light of EUV is absorbed by the absorption layer when reflected by the mirror. Therefore, the quantity of infrared light included in the exposing light used for irradiating the resist film is reduced. As a result, the local thermal absorption by the resist film can be reduced, and the shape of the resist pattern obtained by developing the resist film can be prevented from degrading.

The second pattern formation method of this invention includes the steps of performing pattern exposure by irradiating a resist film formed on a substrate with EUV having been reflected by a reflection mask and a mirror; and forming a resist pattern made of an unexposed portion of the resist film by developing the resist film after the pattern exposure, and the reflection mask includes a reflection layer for reflecting EUV formed on a mask substrate; an EUV absorption layer for absorbing EUV selectively formed on the reflection layer; and an infrared light absorption layer formed above the reflection layer at least in a portion where the EUV absorption layer is not formed and made from a compound for absorbing infrared light.

In the second pattern formation method of this invention, since the infrared light absorption layer made from the compound for absorbing infrared light is formed above the reflection layer of the reflection mask at least in the portion where the EUV absorption layer is not formed, infrared light included in exposing light of EUV is absorbed by the infrared absorption layer when reflected by the reflection mask. Therefore, the quantity of infrared light included in the exposing light used for irradiating the resist film is reduced. As a result, the local thermal absorption by the resist film can be reduced, and the shape of the resist pattern obtained by developing the resist film can be prevented from degrading.

The third pattern formation method of this invention includes the steps of performing pattern exposure by irradiating a resist film formed on a substrate with EUV having been reflected by a reflection mask and a mirror; and forming a resist pattern made of an unexposed portion of the resist film by developing the resist film after the pattern exposure, and the reflection mask includes a reflection layer for reflecting EUV formed on a mask substrate; an EUV absorption layer for absorbing EUV selectively formed on the reflection layer; and an infrared light absorption layer formed above the reflection layer at least in a portion where the EUV absorption layer is not formed and made from a compound for absorbing infrared light, and the mirror includes a reflection layer for reflecting EUV formed on a mirror substrate and an absorption layer formed on the reflection layer and made from a compound for absorbing infrared light.

In the third pattern formation method of this invention, the absorption layer made from the compound for absorbing infrared light is formed on the reflection layer of the mirror, and the infrared light absorption layer made from the compound for absorbing infrared light is formed above the reflection layer of the reflection mask at least in the portion in which the EUV absorption layer is not formed. Therefore, the quantity of infrared light included in the exposing light used for irradiating the resist film is largely reduced. As a result, the shape of the resist pattern obtained by developing the resist film can be definitely prevented from degrading.

In each of the first through third pattern formation methods of this invention, the resist film is preferably made from a chemically amplified resist material.

In each of the first through third pattern formation methods of this invention, the compound is preferably phthalocyanine.

Since phthalocyanine well absorbs infrared light and minimally absorbs EUV as described above, the shape of the resist pattern can be definitely prevented from degrading, and the sensitivity and the resolution of the resist pattern are minimally lowered.

In this case, the phthalocyanine can be copper phthalocyanine, titanium monoxide phthalocyanine, titanium phthalocyanine, hydrogen phthalocyanine, aluminum phthalocyanine, iron phthalocyanine, cobalt phthalocyanine, tin phthalocyanine, copper fluoride phthalocyanine, copper chloride phthalocyanine, copper bromide phthalocyanine or copper iodide phthalocyanine.

In each of the first through third pattern formation methods of this invention, the compound is preferably a cyanine compound, a squalilium compound, an azomethine compound, a xanthene compound, an oxonol compound, an azo compound, an anthraquinone compound, a triphenylmethane compound, a phenothiazine compound or a phenoxazine compound.

In each of the first through third pattern formation methods of this invention, the compound is preferably deposited by sputtering, vacuum evaporation or ion plating.

In this case, the sputtering can be magnetron sputtering, reactive sputtering, diode sputtering, ion beam sputtering, facing target sputtering, ECR sputtering, multiode sputtering or coaxial sputtering; the vacuum evaporation can be molecular beam epitaxial growth, reactive vacuum evaporation, electron beam evaporation, laser beam evaporation, arc process, resistance heating evaporation or induction heating evaporation; and the ion plating can be reactive ion plating, ion beam process or hollow cathode discharge ion plating.

### BRIEF DESCRIPTION OF THE DRAWINGS

FIG. 1 is a cross-sectional view of a reflection mask according to an embodiment of the invention;

FIG. 2 is a cross-sectional view of a reflection mirror according to an embodiment of the invention;

FIGS. 3A, 3B, 3C and 3D are cross-sectional views for showing procedures in a pattern formation method according to an embodiment of the invention;

FIG. 4 is a schematic diagram for showing the whole architecture of an exposure system used in an embodiment of the invention and in conventional technique;

FIGS. 5A, 5B, 5C and 5D are cross-sectional views for showing procedures in a conventional pattern formation method; and

FIGS. 6A, 6B, 6C, 6D, 6E and 6F are diagrams for showing absorbance characteristics of hydrogen phthalocyanine, aluminum phthalocyanine, titanium phthalocyanine, iron phthalocyanine, cobalt phthalocyanine and copper phthalocyanine, respectively.

### DETAILED DESCRIPTION OF THE INVENTION

An embodiment of the invention will now be described with reference to the accompanying drawings.

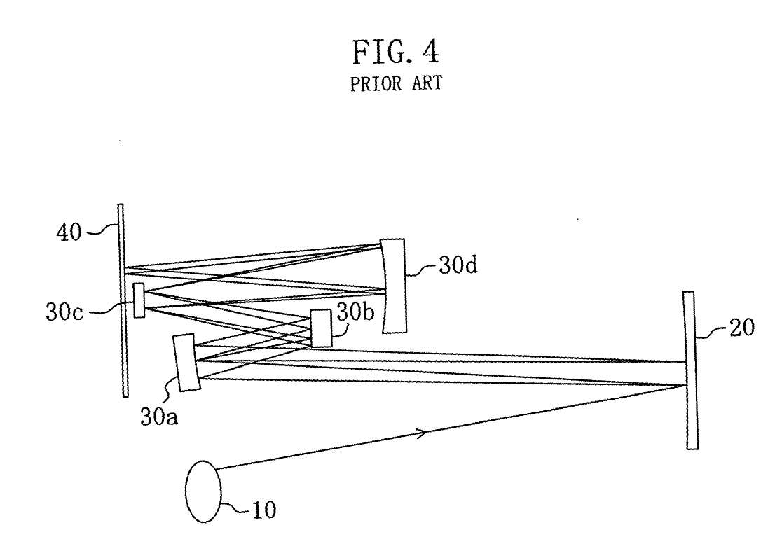

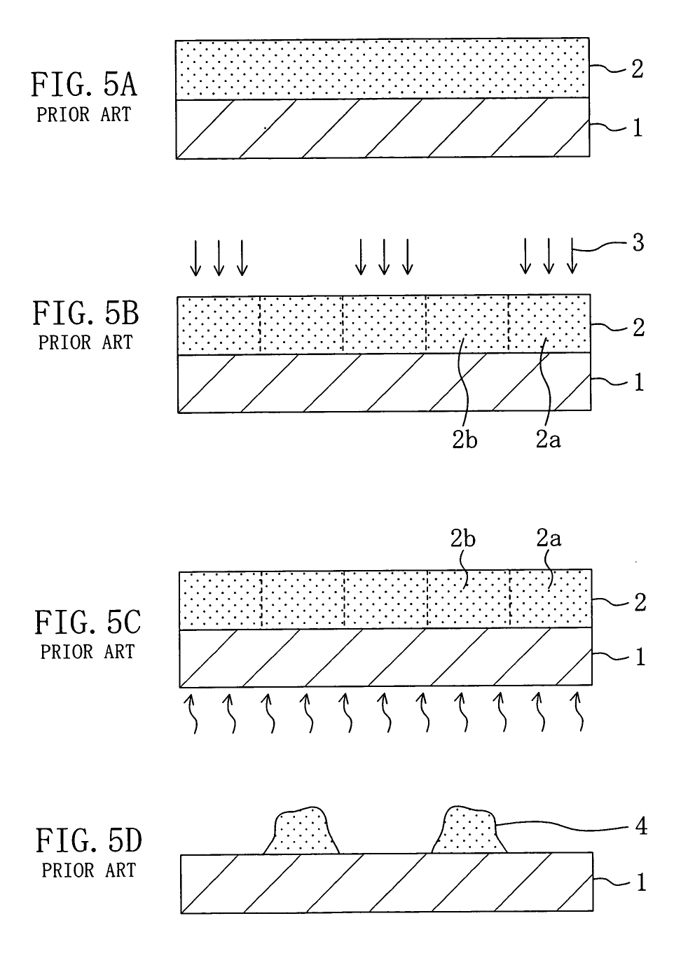

In the embodiment of the invention, as shown in FIG. 4, EUV emitted from an EUV source 10 of laser plasma, SOR or the like is selectively reflected by a reflection mask 20, and then is successively reflected by a first reflection mirror 30a, a second reflection mirror 30b, a third reflection mirror 30c and a fourth reflection mirror 30d, so as to irradiate a resist film formed on a semiconductor wafer 40.

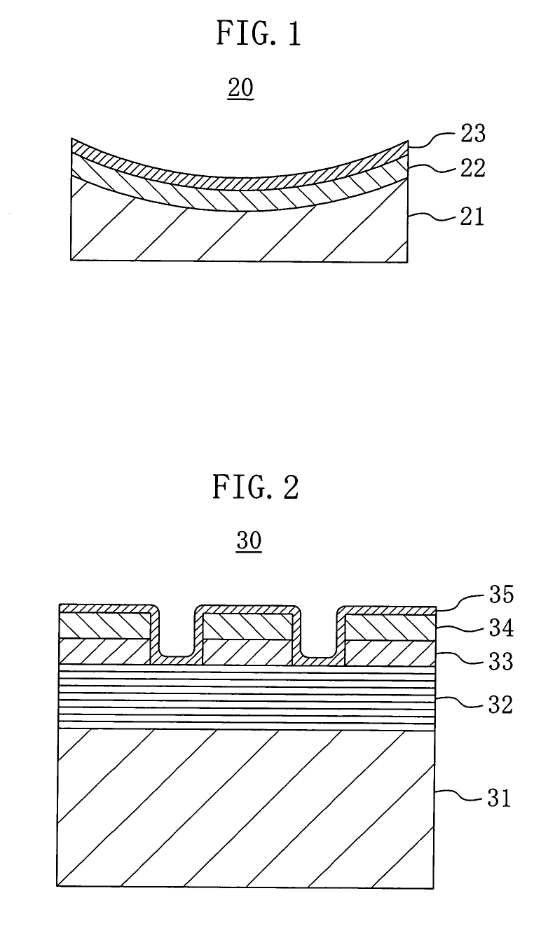

As a characteristic of this embodiment, the reflection mask 20 includes, as shown in FIG. 1, a mirror substrate 21 of platinum or the like; a reflection layer 22 formed on the mirror substrate 21 and made of a multilayer film in which molybdenum and silicon are alternately stacked; and an absorption layer 23 formed on the reflection layer 22 and made from a compound for absorbing infrared light. The absorption layer 23 will be described in detail layer.

Also in this embodiment, each of the first reflection mirror 30a, the second reflection mirror 30b, the third reflection mirror 30c and the fourth reflection mirror 30d includes, as shown in FIG. 2, a mask substrate 31 of silicon or glass; a reflection layer 32 for reflecting EUV formed on the mask substrate 31 and made of a multilayer film in which molybdenum and silicon are alternately stacked; a buffer layer 33 selectively formed on the reflection layer 32 and made from SiO₂, Ru or the like; an EUV absorption layer 34 for absorbing EUV formed on the buffer layer 33 and made from Cr, TaN or the like; and an infrared light absorption layer 35 formed on or above the reflection layer 32 at least in a portion where the EUV absorption layer 34 is not formed and made from a compound for absorbing infrared light. Although the infrared light absorption layer 35 is formed over the reflection layer 32 and the EUV absorption layer 34 in FIG. 2, the infrared light absorption layer 35 may be formed above the reflection layer 32 at least in the portion where the EUV absorption layer 34 is not formed. Also, although the infrared light absorption layer 35 is formed over the reflection layer 32 and the EUV absorption layer 34 in FIG. 2, the infrared light absorption layer 35 may be formed between the reflection layer 32 and the buffer layer 33.

Furthermore, although each of the first reflection mirror 30a, the second reflection mirror 30b, the third reflection mirror 30c and the fourth reflection mirror 30d includes the infrared light absorption layer 35 in this embodiment, at least one of the first through fourth reflection mirrors 30a, 30b, 30c and 30d may include the infrared light absorption layer 35.

Also, although both the reflection mask and the reflection mirrors include the absorption layers made from the compound for absorbing infrared light in this embodiment, either of the reflection mask or the reflection mirrors may include the absorption layer made from the compound for absorbing infrared light.

Now, the compound for absorbing infrared light used in the absorption layer 23 of the reflection mask 20 and the infrared light absorption layer 35 of the first through fourth reflection mirrors 30a through 30d will be described.

The compound for absorbing infrared light is preferably phthalocyanine represented by Chemical Formula 1:

Chemical Formula 1:

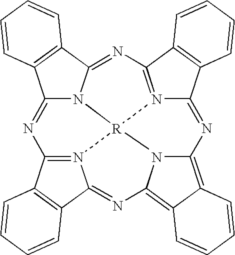

wherein R is a substituent.

Examples of the phthalocyanine are copper phthalocyanine (R═Cu), titanium monoxide phthalocyanine (R═TiO), titanium phthalocyanine (R═Ti), hydrogen phthalocyanine (R═H), aluminum phthalocyanine (R═Al), iron phthalocyanine (R═Fe), cobalt phthalocyanine (R═Co), tin phthalocyanine (R═Sn), copper fluoride phthalocyanine (R═CuF₂), copper chloride phthalocyanine (R═CuCl₂), copper bromide phthalocyanine (R═CuBr) and copper iodide phthalocyanine (R═CuI).

Since phthalocyanine well absorbs infrared light, exposing light used for irradiating a resist film minimally includes infrared light. Therefore, local thermal absorption by the resist film can be avoided, so as to definitely prevent degradation of the shape of a resist pattern to be formed. Furthermore, since phthalocyanine minimally absorbs EUV, the quantity of EUV used for irradiating the resist film is not reduced, and hence, the sensitivity and the resolution of the resist pattern to be formed are minimally degraded. Moreover, phthalocyanine is very stable in a high vacuum atmosphere in which the resist film is irradiated with EUV.

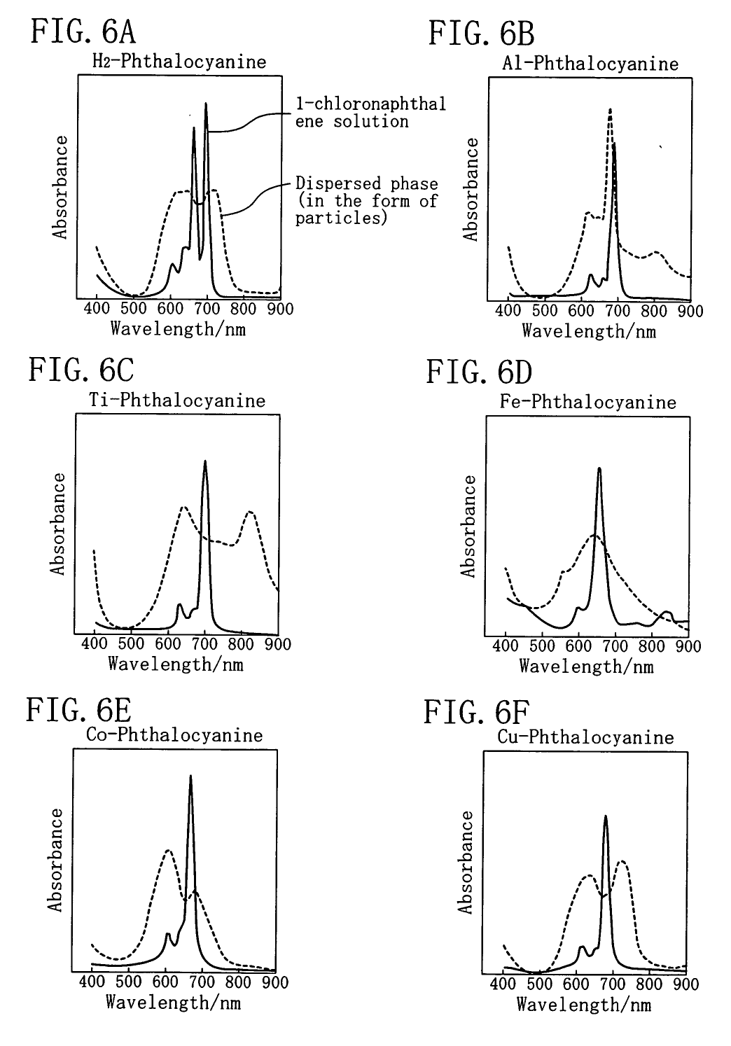

FIG. 6A shows the absorbance characteristic of hydrogen phthalocyanine, FIG. 6B shows the absorbance characteristic of aluminum phthalocyanine, FIG. 6C shows the absorbance characteristic of titanium phthalocyanine, FIG. 6D shows the absorbance characteristic of iron phthalocyanine, FIG. 6E shows the absorbance characteristic of cobalt phthalocyanine, and FIG. 6F shows the absorbance characteristic of copper phthalocyanine. In each of FIGS. 6A through 6F, a solid line indicates the absorption spectrum obtained when the corresponding compound is dissolved in a chloronaphthalene solution, and a broken line indicates the absorption spectrum obtained when the corresponding compound is in a dispersion phase.

As shown in FIGS. 6A through 6F, each phthalocyanine compound has a particularly large absorbance characteristic in the infrared light region of a wavelength of a 650 nm through 750 nm band, and this reveals that each phthalocyanine compound is good at a characteristic to absorb infrared light.

The amount of the compound for absorbing infrared light is not particularly specified. In order to efficiently absorb infrared light, the thickness of the film of the compound for absorbing infrared light may be 10 μm or less.

Also, as the compound for absorbing infrared light, phthalocyanine may be replaced with a cyanine compound, a squalilium compound, an azomethine compound, a xanthene compound, an oxonol compound, an azo compound, an anthraquinone compound, a triphenylmethane compound, a phenothiazine compound or a phenoxazine compound.

Furthermore, the film of the compound for absorbing infrared light may be deposited by sputtering, such as magnetron sputtering, reactive sputtering, diode sputtering, ion beam sputtering, facing target sputtering, ECR sputtering, multiode sputtering or coaxial sputtering; by vacuum evaporation, such as molecular beam epitaxial growth, reactive vacuum evaporation, electron beam evaporation, laser beam evaporation, arc process, resistance heating evaporation or induction heating evaporation; or by ion plating, such as reactive ion plating, ion beam process or hollow cathode discharge ion plating.

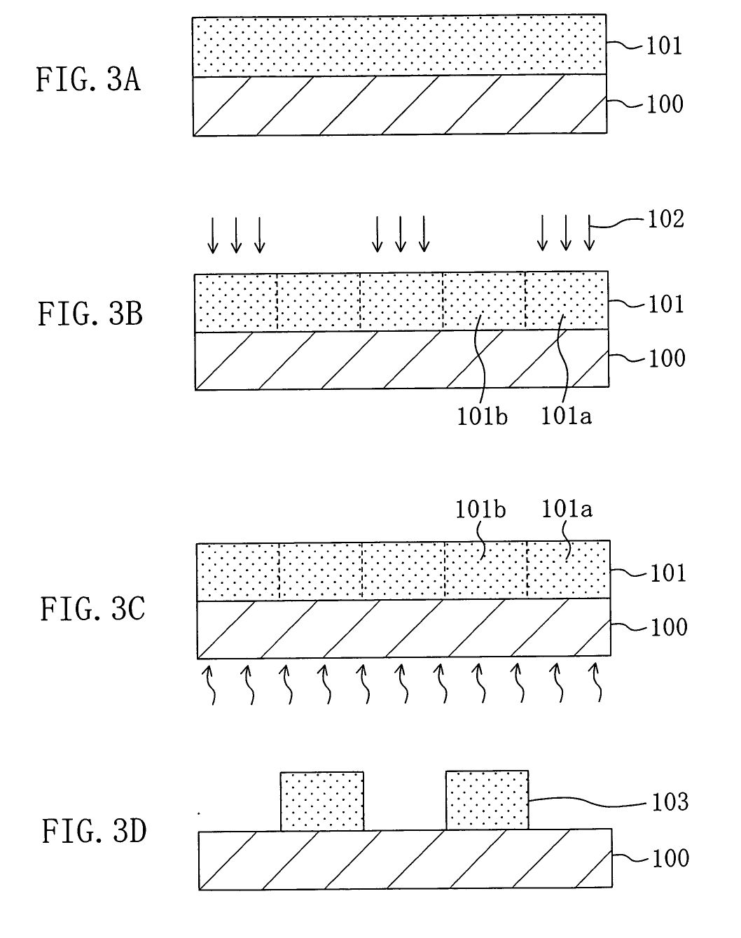

Now, a method for forming a resist pattern by using the exposure system including the reflection mask 20 and the first through fourth reflection mirrors 30a through 30d will be described with reference to FIGS. 3A through 3D.

First, a chemically amplified resist material having the following composition is prepared:

Base polymer: poly((p-t-butyloxycarbonyloxystyrene)−(hydroxystyrene)) (wherein p-t-butyloxycarbonyloxystyrene: hydroxystyrene=40 mol %:60 mol %) . . . 4.0 g

Acid generator: triphenylsulfonium nonafluorobutanesulfonate . . . 0.12 g

Solvent: propylene glycol monomethyl ether acetate . . . 20 g

Next, as shown in FIG. 3A, the aforementioned chemically amplified resist material is applied on a substrate 100, so as to form a resist film 101 with a thickness of 0.15 μm.

Then, as shown in FIG. 3B, pattern exposure is carried out by irradiating the resist film 101 with EUV 102 (of a wavelength of a 13.5 nm band) having been emitted by the EUV exposure system with numerical aperture (NA) of 0.10 and successively reflected by the reflection mask 20 and the first through fourth reflection mirrors 30a through 30d.

After the pattern exposure, as shown in FIG. 3C, the resist film 101 is subjected to post-exposure bake with a hot plate at a temperature of 100° C. for 60 seconds. Thus, an exposed portion 101a of the resist film 101 becomes soluble in an alkaline developer because an acid is generated from the acid generator therein while an unexposed portion 101b of the resist film 101 remains to be insoluble in an alkaline developer because no acid is generated from the acid generator therein.

After the post-exposure bake, the resist film 101 is developed with a 2.38 wt % tetramethylammonium hydroxide developer (alkaline developer). Thus, a resist pattern 103 made of the unexposed portion 101b of the resist film 101 can be formed in a good cross-sectional shape as shown in FIG. 3D.

Now, an exemplified experiment carried out for evaluating the embodiment of the invention will be described.

A resist pattern 103 is formed through the procedures shown in FIGS. 3A through 3D by using an exposure system. This exposure system includes a reflection mask 20 having an absorption layer 23 made from copper phthalocyanine (i.e., the compound for absorbing infrared light) evaporated by the molecular beam epitaxial growth, and three of first through fourth reflections mirrors 30a through 30d of this exposure system have infrared light absorption layers 35 made from copper phthalocyanine (i.e., the compound for absorbing infrared light) evaporated by the molecular beam epitaxial growth.

In this experiment, infrared light included in the exposing light is effectively absorbed by the reflection mask and the reflection mirrors. Accordingly, the resultant resist pattern 103 is in a rectangular cross-sectional shape and has a pattern width of 87.3 nm when a reflection area of the reflection mask has a pattern width of 90 nm. Specifically, the reduction ratio of the pattern width of the resist pattern 103 to the pattern width of the reflection mask is as low as 3%.

What is claimed is:

1. A mirror for use in an exposure system comprising:
a reflection layer for reflecting EUV formed on a mirror substrate; and
an absorption layer formed on said reflection layer and made from a compound for absorbing infrared light.

2. The mirror for use in an exposure system of claim 1,
wherein said compound is phthalocyanine.

3. The mirror for use in an exposure system of claim 2,
wherein said phthalocyanine is copper phthalocyanine.

4. The mirror for use in an exposure system of claim 2,
wherein said phthalocyanine is titanium monoxide phthalocyanine, titanium phthalocyanine, hydrogen phthalocyanine, aluminum phthalocyanine, iron phthalocyanine, cobalt phthalocyanine, tin phthalocyanine, copper fluoride phthalocyanine, copper chloride phthalocyanine, copper bromide phthalocyanine or copper iodide phthalocyanine.

5. The mirror for use in an exposure system of claim 1,
wherein said compound is a cyanine compound, a squalilium compound, an azomethine compound, a xanthene compound, an oxonol compound, an azo compound, an anthraquinone compound, a triphenylmethane compound, a phenothiazine compound or a phenoxazine compound.

6. The mirror for use in an exposure system of claim 1,
wherein said compound is deposited by sputtering, vacuum evaporation or ion plating.

7. The mirror for use in an exposure system of claim 1,
wherein said compound is deposited by magnetron sputtering, reactive sputtering, diode sputtering, ion beam sputtering, facing target sputtering, ECR sputtering, multiode sputtering or coaxial sputtering.

8. The mirror for use in an exposure system of claim 1,
wherein said compound is deposited by molecular beam epitaxial growth, reactive vacuum evaporation, electron beam evaporation, laser beam evaporation, arc process, resistance heating evaporation or induction heating evaporation.

9. The mirror for use in an exposure system of claim 1,
wherein said compound is deposited by reactive ion plating, ion beam process or hollow cathode discharge ion plating.

10. The mirror for use in an exposure system of claim 1,
wherein said reflection layer includes molybdenum or silicon.

11. A reflection mask for use in an exposure system comprising:
a reflection layer for reflecting EUV formed on a mask substrate;
an EUV absorption layer for absorbing EUV selectively formed on said reflection layer; and
an infrared light absorption layer formed above said reflection layer at least in a portion where said EUV absorption layer is not formed and made from a compound for absorbing infrared light.

12. An exposure system comprising a mirror,
said mirror including a reflection layer for reflecting EUV formed on a mirror substrate; and an absorption layer formed on said reflection layer and made from a compound for absorbing infrared light.

13. An exposure system comprising a reflection mask,
said reflection mask including a reflection layer for reflecting EUV formed on a mask substrate; an EUV absorption layer for absorbing EUV selectively formed on said reflection layer; and an infrared light absorption layer formed above said reflection layer at least in a portion where said EUV absorption layer is not formed and made from a compound for absorbing infrared light.

14. An exposure system comprising:
a mirror including a reflection layer for reflecting EUV formed on a mirror substrate and an absorption layer formed on said reflection layer and made from a compound for absorbing infrared light; and
a reflection mask including a reflection layer for reflecting EUV formed on a mask substrate, an EUV absorption layer for absorbing EUV selectively formed on said reflection layer, and an infrared light absorption layer formed above said reflection layer at least in a portion where said EUV absorption layer is not formed and made from a compound for absorbing infrared light.

15. A pattern formation method comprising the steps of:
performing pattern exposure by irradiating a resist film formed on a substrate with EUV having been reflected by a reflection mask and a mirror; and
forming a resist pattern made of an unexposed portion of said resist film by developing said resist film after the pattern exposure,
wherein said mirror includes a reflection layer for reflecting EUV formed on a mirror substrate and an absorption layer formed on said reflection layer and made from a compound for absorbing infrared light.

16. The pattern formation method of claim 15,
wherein said resist film is made from a chemically amplified resist material.

17. A pattern formation method comprising the steps of:
performing pattern exposure by irradiating a resist film formed on a substrate with EUV having been reflected by a reflection mask and a mirror; and
forming a resist pattern made of an unexposed portion of said resist film by developing said resist film after the pattern exposure,
wherein said reflection mask includes a reflection layer for reflecting EUV formed on a mask substrate; an EUV absorption layer for absorbing EUV selectively formed on said reflection layer; and an infrared light absorption layer formed above said reflection layer at least in a portion where said EUV absorption layer is not formed and made from a compound for absorbing infrared light.

18. The pattern formation method of claim 17,
wherein said resist film is made from a chemically amplified resist material.

19. A pattern formation method comprising the steps of:
performing pattern exposure by irradiating a resist film formed on a substrate with EUV having been reflected by a reflection mask and a mirror; and
forming a resist pattern made of an unexposed portion of said resist film by developing said resist film after the pattern exposure,
wherein said reflection mask includes a reflection layer for reflecting EUV formed on a mask substrate; an EUV absorption layer for absorbing EUV selectively formed on said reflection layer; and an infrared light absorption layer formed above said reflection layer at least in a portion where said EUV absorption layer is not formed and made from a compound for absorbing infrared light, and
said mirror includes a reflection layer for reflecting EUV formed on a mirror substrate and an absorption layer formed on said reflection layer and made from a compound for absorbing infrared light.

20. The pattern formation method of claim 19,
wherein said resist film is made from a chemically amplified resist material.
